(19) United States
(12) Patent Application Publication
(10) Pub. No.: US 2001/0049196 A1
(43) Pub. Date: Dec. 6, 2001

(54) APPARATUS FOR IMPROVING ETCH UNIFORMITY AND METHODS THEREFOR

(76) Inventors: ROGER PATRICK, MOUNTAIN VIEW, CA (US); PHILLIP L. JONES, FREMONT, CA (US)

Correspondence Address: BEYER WEAVER & THOMAS LLP, P.O. BOX 778, BERKELEY, CA, 94704-0778, US

(21) Appl. No.: 08/925,985

(22) Filed: Sep. 9, 1997

(51) Int. Cl. H01L 21/461; C25B 9/00; H01L 21/302; C23C 14/00; C23C 16/00; C25B 13/00; C25B 11/00

(52) U.S. Cl. 438/689; 438/729; 156/345; 204/298.15; 204/298.34; 118/728

(57) ABSTRACT

A method in a plasma processing chamber for improving etch uniformity while etching a semiconductor substrate. The method includes placing the semiconductor substrate into a sacrificial substrate holder. The sacrificial substrate holder is configured to present a sacrificial etch portion surrounding the semiconductor substrate to a plasma within the plasma processing chamber to permit the plasma to etch a first surface of the semiconductor substrate and a first surface of the sacrificial etch portion simultaneously. The first surface of the sacrificial etch portion is formed of a material capable of being etched by the plasma. The method further includes positioning the semiconductor substrate and the sacrificial substrate holder into the plasma processing chamber. There is also included striking the plasma from an etchant source gas released into the plasma processing chamber. Additionally, there is included simultaneously etching the first surface of the semiconductor substrate and the first surface of the sacrificial etch portion using the plasma.

### BACKGROUND OF THE INVENTION

The present invention relates to the processing of semiconductor substrates. More particularly, the present invention relates to methods and apparatus for improving etch uniformity while etching a semiconductor substrate in a plasma processing chamber.

In the fabrication of semiconductor integrated circuits (IC) or flat panel displays, a substrate may at times be masked and etched to form desired patterns on the substrate surface. Although different etch techniques exist, plasma enhanced etching in an appropriate plasma processing chamber has been found to be beneficial in improving the etch profile, etch uniformity, etch selectivity, substrate throughput and/or the like.

In plasma enhanced etching, the substrate with one or more layers disposed thereon is first masked using a suitable photoresist technique. By way of example, one such photoresist technique involves the deposition of a photoresist layer atop the layer to be etched, and the patterning of the photoresist layer by exposing the photoresist material in a contact or stepper lithography system. Thereafter, the photoresist material is developed to form a mask to facilitate subsequent etching. The substrate is then introduced into a plasma processing chamber wherein a plasma is struck from an appropriate etchant source gas. The reactive etchant species in the plasma attack areas of the substrate that are unprotected by the mask, leaving behind the desired pattern.

To facilitate discussion, FIG. 1 illustrates a simplified plasma processing system, including a substrate 102 disposed within a plasma processing chamber 104. Substrate 102 is disposed on top of a chuck 106, which may represent either an electrostatic chuck or a chuck having a mechanical clamp to hold substrate 102 in place during etching. Through showerhead 108, an appropriate etchant source gas is released into a plasma region 110 within the plasma processing chamber. The etchant source gas may also be released via a gas ring disposed inside the chamber or via ports built into the walls of the chamber. Application of RF power, using one or more RF power supplies, to electrodes of the plasma processing chamber, e.g., showerhead 108 and/or chuck 106, ignites the etchant source gas, thereby forming a plasma cloud 112 above substrate 102. As discussed earlier, the exposed areas of substrate 102 may then be etched by the reactive species of plasma cloud 112. The etch byproducts are then exhausted away via outlet 126.

It has been found in examining some post-etch substrates that there exists a preferential edge effect, which renders the etch rate nonuniform across the substrate surface. The preferential edge effect shows a nontrivial increase in the etch rate at the substrate edge relative to other regions of the substrate, e.g., the center region. With reference to FIG. 1, for example, the preferential edge effect causes the etch rate in the vicinity of substrate edge 120 to be higher than the etch rate in other regions of the substrate. It is believed that the preferential edge effect may be caused by the existence of a localized reactant depletion region over the center of substrate 102. It is further believed that the density of reactive species decreases in this localized reactant depletion region as the reactive species react with the bulk of the substrate's surface. The reactant depletion is less noticeable at the substrate edge since there is less substrate surface at the edge with which to react. Accordingly, the density of reactive species is believed to be higher at the substrate edge (e.g., substrate edge 120 in FIG. 1). Since the reactant density is higher at the substrate edge relative to the reactant density in the localized reactant depletion region, which tends to exist in the vicinity of the substrate center, a higher etch rate is observed at the substrate edge. It is also believed that there is some back diffusion of reactive species at substrate edge 120. The back diffusion, whose direction is depicted in FIG. 1 by arrow 130, introduces additional reactive species to the substrate edge, thereby increasing the etch rate at the substrate edge.

FIG. 2 is a highly simplified plot of the etch rates across an 8-inch wafer, showing the preferential edge effect at points 202 and 204 at the substrate edge. Due to the presence of the localized reactant depletion region about the center of the substrate, the etch rate at point 206 is shown to be slower than the etch rate at the substrate edge (points 202 and 204).

To improve etch uniformity across the substrate, efforts have been made to compensate for the aforementioned preferential edge effect. In one case, reactant source gas is preferentially flowed to the center region of the substrate. By way of example, the injection ports in showerhead 108 may be arranged such that a greater number of injection ports exists over the center region of substrate 102 relative to the substrate edge region. Accordingly, a greater volume of reactant gas is directed toward the center region of substrate 102 (where a localized reactant depletion region tends to develop). In this manner, preferential injection increases the density of reactive species in the region believed to suffer from a localized reactant depletion.

The increase in the density of reactive species over the center region of substrate 102 tends to raise the etch rate in this region. Depending on the design of the showerhead injection port pattern, preferential injection may raise the etch rate over the center region to approach or even exceed that at the substrate edge. By way of example, FIG. 3 depicts a highly simplified plot of the etch rates across a substrate wherein preferential injection is employed to increase the density of reactive species, and concomitantly the etch rate, over the center region of substrate 102. As shown in FIG. 3, the etch rate increases in the vicinity of point 302 due to the increased density of reactive species over the center region of the substrate. The etch rate increases again at points 304 and 306 due to the aforementioned preferential edge effect.

As illustrated in FIG. 3, however, there still exists localized regions of low etch rates, e.g., in the vicinity of points 308 and 310. While preferential injection may offer some improvement in etch uniformity, the differential in the etch rates across the substrate may still be sufficiently high to render some etch processes unsatisfactory.

In view of the foregoing, there are desired improved techniques for improving etch uniformity while etching a semiconductor substrate in a plasma processing chamber.

### SUMMARY OF THE INVENTION

The present invention relates, in one embodiment, to a method in a plasma processing chamber for improving etch uniformity while etching a semiconductor substrate. The method includes placing the semiconductor substrate into a sacrificial substrate holder. The sacrificial substrate holder is configured to present a sacrificial etch portion surrounding the semiconductor substrate to a plasma within the plasma processing chamber to permit the plasma to etch a first surface of the semiconductor substrate and a first surface of the sacrificial etch portion simultaneously. The first surface of the sacrificial etch portion is formed of a material capable of being etched by the plasma.

The method further includes positioning the semiconductor substrate and the sacrificial substrate holder into the plasma processing chamber. There is also included striking the plasma from an etchant source gas released into the plasma processing chamber. Additionally, there is included simultaneously etching the first surface of the semiconductor substrate and the first surface of the sacrificial etch portion using the plasma.

In another embodiment, the invention relates to a sacrificial substrate holder for improving etch uniformity while etching a semiconductor substrate in a plasma processing chamber. The sacrificial substrate holder includes a sacrificial etch portion configured to surround the semiconductor substrate. The sacrificial etch portion includes a first surface comprising a material capable of being etched by a plasma configured to etch the semiconductor substrate when the semiconductor substrate and the sacrificial substrate holder are disposed on a chuck within the plasma processing chamber. The first surface of the sacrificial etch portion is substantially parallel to a first surface of the semiconductor substrate when the semiconductor substrate and the sacrificial substrate holder are disposed on the chuck within the plasma processing chamber, thereby permitting the plasma to etch the first surface of the semiconductor substrate and the first surface of the sacrificial etch portion simultaneously.

These and other advantages of the present invention will become apparent upon reading the following detailed descriptions and studying the various figures of the drawings.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a simplified plasma processing system to facilitate discussion.

FIG. 2 is a simplified plot of the etch rates across a wafer, showing the preferential edge effect at the substrate edge.

FIG. 3 depicts a simplified plot of the etch rates across the wafer of FIG. 2 wherein preferential injection is employed to alleviate the preferential edge effect.

FIG. 4 illustrates a top view of a sacrificial substrate holder, including a sacrificial etch portion in accordance with one embodiment of the present invention.

FIG. 5 depicts, in accordance with one embodiment of the present invention, a combination sacrificial etch portion/substrate to be disposed in a plasma processing chamber for etching.

FIG. 6 illustrates, in accordance with one aspect of the present invention, the steps involved in improving etch uniformity using the disclosed sacrificial substrate holder.

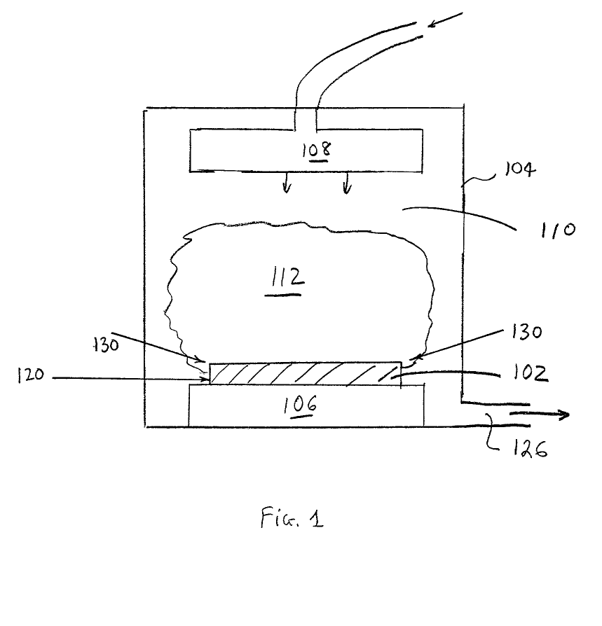

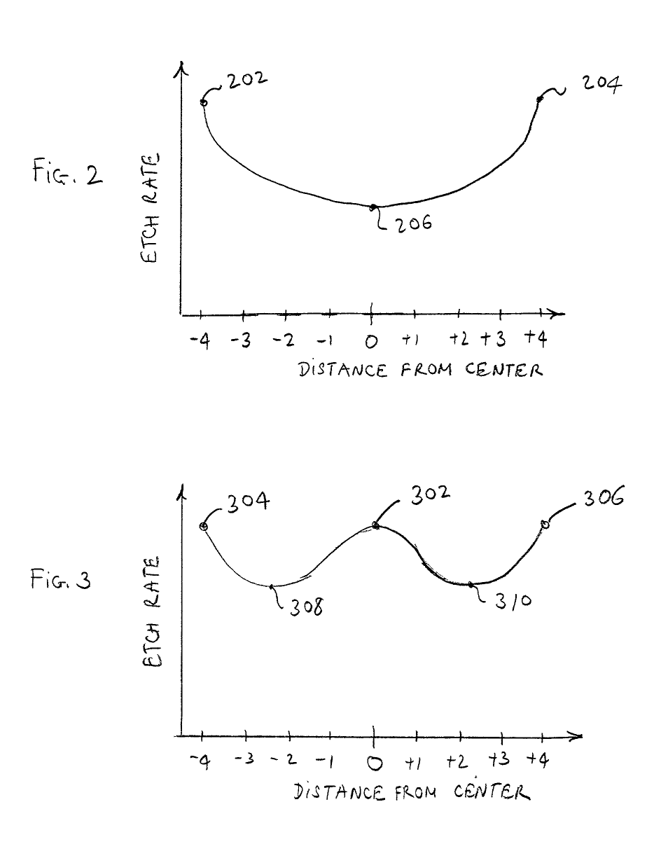

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps have not been described in detail in order to not unnecessarily obscure the present invention.

In accordance with one aspect of the present invention, the aforementioned etch rate nonuniformity due to the preferential edge effect is advantageously alleviated by employing a sacrificial substrate holder while etching the semiconductor substrate. The sacrificial substrate holder includes a sacrificial etch portion surrounding the semiconductor substrate, the surface of which is parallel to the surface of the substrate to be etched. Preferably, the surface of the sacrificial etch portion is formed of a material whose etch byproducts is substantially volatile, i.e., the byproduct may be easily evacuated from the plasma processing chamber without leaving much residue.

During etching, the plasma cloud is permitted to extend into the sacrificial etch portion such that preferential edge effect, if any, would increase the etch rate mainly over the sacrificial etch portion. Over the substrate (and possibly over the inner portion of the sacrificial etch portion), the etch rate may therefore remain more uniform.

It is contemplated that the invention disclosed herein may be performed in any plasma processing system. By way of example, it is contemplated that the invention may be practiced in plasma processing chambers adapted for dry etching, reactive ion etching (RIE), magnetically enhanced reactive ion etching (MERIE), electron cyclotron resonance (ECR), or the like. Note that the above is true irrespective of whether the plasma is a high density plasma (e.g., having density above about 1013/cm3), whether energy to the plasma is delivered through capacitively coupled parallel electrode plates, through ECR microwave plasma sources, or through inductively coupled RF sources such as helicon, helical resonators, and transformer coupled plasma. ECR and TCP™ (transformer coupled plasma) processing systems, among others, are readily available commercially. TCP™ systems are available from, for example, Lam Research Corporation of Fremont, Calif. In a preferred embodiment, the invention is practiced a member of the 9600™ plasma etcher family from Lam Research Corporation (e.g., a 9600™, a 9600 SE™ or a 9600 PTX™).

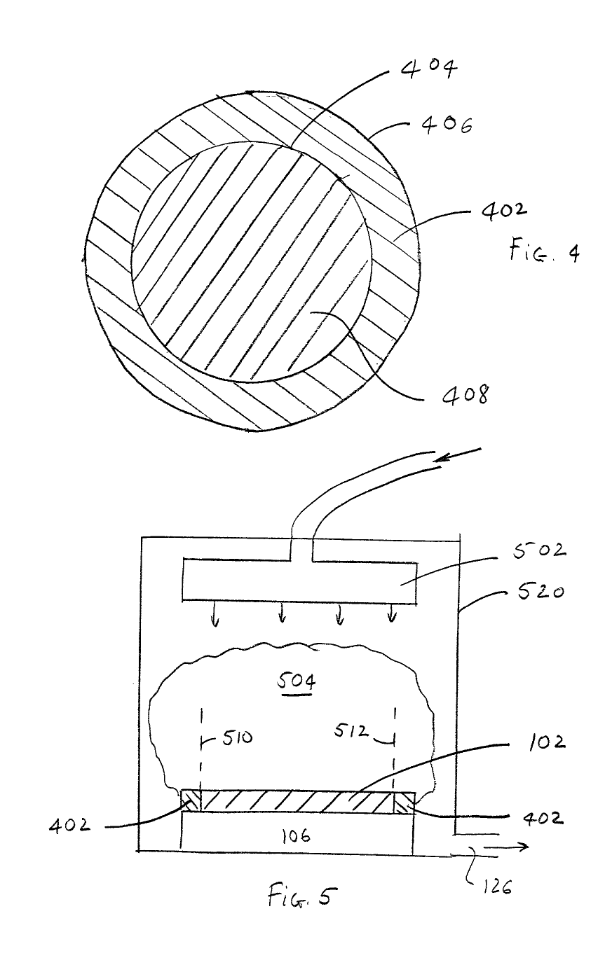

The features and advantages of the present invention may be more fully appreciated with reference to the figures and discussions below. FIG. 4 illustrates a top view of a sacrificial substrate holder, including a sacrificial etch portion 402, which has an inner circumference 404 and an outer circumference 406. Sacrificial etch portion 402 has a surface formed of a material capable of being etched by the same plasma employed to etch the semiconductor substrate. Inside inner circumference 404, there exists a substrate-bearing portion 408, which may represent a depression in or a hollow through the sacrificial substrate holder. During etching, the substrate is disposed within substrate bearing portion 408 and the sacrificial substrate holder, including the substrate disposed therein, is positioned on top of a chuck or the work piece holder in the plasma processing chamber for etching.

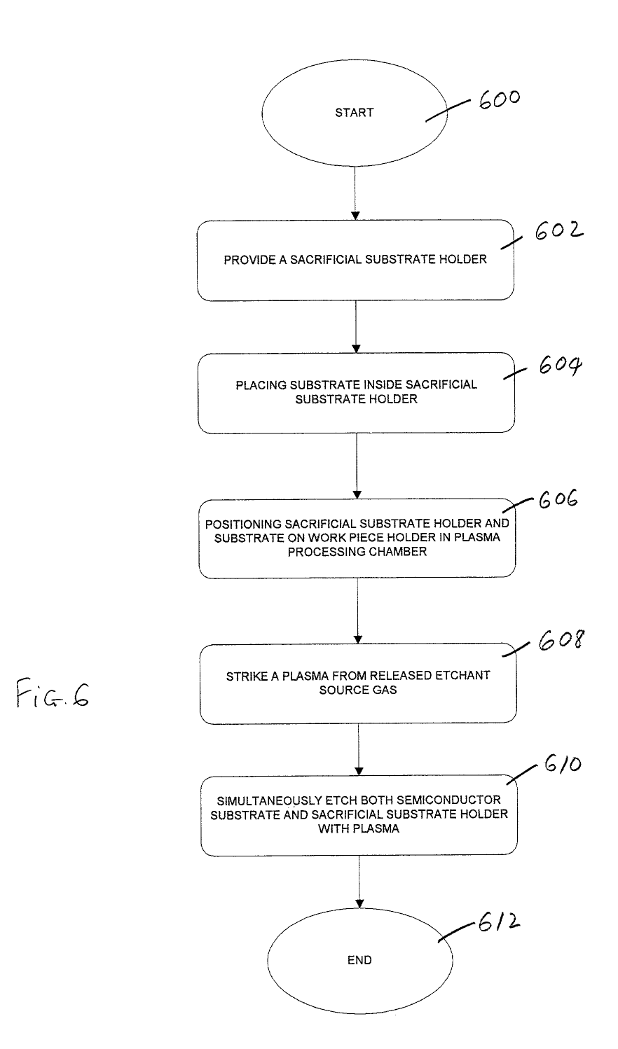

FIG. 5 depicts sacrificial etch portion 402 and substrate 102 as they are disposed on top of chuck 106 during etching. Showerhead 502 represents a showerhead having a uniform injection port pattern although, as will be discussed later, showerhead 502 may represent a preferential injection type showerhead if desired. During etching, a plasma cloud 504 is shown covering substrate 102 and preferably extending beyond the edge of sacrificial etch portion 402. The combined surface area of sacrificial etch portion 402 and the substrate appears to the plasma cloud as a larger substrate. Therefore, even if the edge of the combined structure is etched more preferentially, this may have little, if any, effect on the etch uniformity over the substrate. With reference to FIG. 5, the use of sacrificial etch portion 402 renders the etch rate more uniform between dash lines 510 and 512.

Further, any back diffusion of the reactant species would have little, if any, effect on the etch rate over substrate 102. This is because the back diffusion affects primarily the etch rate over the sacrificial etch portion and tends to have little, if any, effect over the etch rate at the edge of substrate 102. As mentioned, the surface or the entire sacrificial etch portion 402 is preferably formed of a material whose etch byproducts is relatively volatile, i.e., whose byproducts can be readily evacuated from the chamber. Accordingly, the etching of the sacrificial etch portion leaves little, if any, contamination or residue in plasma processing chamber 520.

By way of example, a sacrificial etch portion formed of substantially pure aluminum tends to work well for metallization etches (e.g., etching of the aluminum alloy layer on top of substrate 102 using, for example, a chlorine-containing etchant such as Cl₂/BCl₃). It is possible that sacrificial etch portion 402 may be made of the same material as the substrate layer being etched. However, such is not a necessity, and any material capable of being etched away by the plasma cloud while causing relatively little contamination and/or leaving relatively little residue may generally be employed.

In one embodiment, the sacrificial substrate holder is configured such that the top surface of substrate 102 is flushed with the top surface of sacrificial etch portion 402, although this is not an absolute requirement. The sacrificial substrate holder may have the same thickness as substrate 102, in which case the substrate bearing portion is essentially a hollow through the sacrificial substrate holder to permit the backside of the substrate to be in direct contact with the chuck or work piece holder during etching. Alternatively, the sacrificial substrate holder may be formed of a thicker slab of material, whose interior has been scooped out to accommodate substrate 102, in which case the substrate is nested within the sacrificial substrate holder during etching.

Depending on the size of substrate 102, sacrificial etch portion 402 should be sufficiently wide to render the etch over the substrate uniform at the desired uniformity level. However, an unduly wide sacrificial etch portion 402 may introduce too much target etch material into the plasma processing chamber, which may unduly lower the concentration of the reactive species therein, thereby disadvantageously lowering the overall etch rate and reducing throughput. Conversely, an unduly narrow sacrificial etch portion may be insufficient to compensate for the preferential edge effect to improve the etch uniformity over the substrate.

In general, substrate 102 may be of any size and may be circular in shape (e.g., a wafer) or may assume any geometric shape desired (e.g., square or rectangular as in the case of glass panels). The sacrificial etch portion should be appropriately shaped such that the substrate sits snugly inside the sacrificial etch portion irrespective of the specific shape of the substrate.

As mentioned earlier, the showerhead within the plasma processing chamber may have its injection ports arranged in any suitable pattern to optimize etch uniformity. In the example of FIG. 5, showerhead 502 has its injection ports arranged in a substantially uniform pattern throughout the lower surface of the showerhead although other injections patterns (e.g., preferential injection pattern) may also be employed. By way of example, the injection ports may be concentrated around the center of the shower head (e.g., within a 1-inch circle) if desired. A particular combination of showerhead injection port pattern/sacrificial etch portion configuration may be empirically determined for a particular etch in a particular plasma processing chamber by one skilled in the art given this disclosure.

FIG. 6 illustrates, in accordance with one aspect of the present invention, the steps involved in improving etch uniformity using the disclosed sacrificial substrate holder. In step 602, a sacrificial substrate holder is provided. In step 604, the substrate is placed inside the substrate holder to permit the plasma to etch the sacrificial etch portion of the sacrificial substrate holder and the substrate surface together. In step 606, the sacrificial substrate holder and the substrate are positioned on the work piece holder (e.g., a chuck) within the plasma processing chamber. In step 608, a plasma is struck within the plasma processing chamber from the released etchant source gas to simultaneously etch (step 610) the surface of the semiconductor substrate and the surface of the sacrificial etch portion, thereby improving etch uniformity over the substrate surface.

### EXAMPLE

In one example, an 8-inch wafer having thereon a metallization layer comprising aluminum and about 1% silicon is etched in the aforementioned 9600SE™ plasma processing chamber. The shower head employed for the etch is a preferential center injection type shower head, with the injection ports centered within a 1-inch circle on the head. The sacrificial etch portion is about 0.56 inch wide and is formed of 99.999% pure aluminum. Using the etch recipe of Table 1, improved etch rate uniformity above etches performed without a sacrificial substrate holder is observed.

TABLE 1

| | |
|---|---|
| Chamber Pressure (mTorr) | 12 |
| Top Power (W) | 350 |
| Bottom Power (W) | 132 |
| Flow rate of BCl₃ (sccm) | 75 |
| Flow rate of Cl₂ (sccm) | 75 |
| Helium cooling pressure (Torr) | 8 |
| Duration (seconds) | 50 |

As can be appreciated from the foregoing, the invention advantageously improves etch uniformity across the substrate without requiring time-consuming or expensive etch processes or etch equipment. The use of a sacrificial substrate holder to address the etch uniformity problem makes it possible to retrofit, in a simple and inexpensive manner, existing plasma processing chambers to offer the benefits of the present invention, thereby permitting manufacturers to continue leveraging their investment in existing semiconductor manufacturing equipment. In a nonobvious manner, the invention intentionally introduces an additional consumable structure into the chamber to solve the preferential edge effect problem. This intentional introduction of a consumable structure goes against the current trend in minimizing reactant usage and chamber contamination by reducing the number of consumable structures that can be attacked during the etch.

It has been found that the invention may also, in some cases, be useful in decreasing the amount of polymer deposition on showerhead 502. Polymer deposition occurs during the etch as the photoresist mask is partially eroded and forms polymers within plasma processing chamber 520. On showerhead 502, polymer deposits preferentially on regions without injection ports. As etch rate uniformity is improved through the use of sacrificial etch portion 402, the need for arranging the injection ports in a nonuniform pattern (e.g., to form a preferential injection pattern) is reduced. Accordingly, the injection port may be more uniformly distributed throughout the lower surface of showerhead 502, thereby advantageously reduces the areas available for the preferential deposition of polymer. The result is a cleaner showerhead, which advantageously increases the interval between required cleanings.

While this invention has been described in terms of several preferred embodiments, there are alterations, permutations, and equivalents which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. In a plasma processing chamber, a method for improving etch uniformity while etching a semiconductor substrate, comprising:
placing said semiconductor substrate into a sacrificial substrate holder, said sacrificial substrate holder being configured to present a sacrificial etch portion surrounding said semiconductor substrate to a plasma within said plasma processing chamber to permit said plasma to etch a first surface of said semiconductor substrate and a first surface of said sacrificial etch portion simultaneously, said first surface of said sacrificial etch portion being formed of a material capable of being etched by said plasma;
positioning said semiconductor substrate and said sacrificial substrate holder into said plasma processing chamber;
striking said plasma from an etchant source gas released into said plasma processing chamber; and
simultaneously etching said first surface of said semiconductor substrate and said first surface of said sacrificial etch portion using said plasma.

2. The method of claim 1 wherein said semiconductor substrate represents a wafer and wherein said sacrificial etch portion represents a ring surrounding said wafer.

3. The method of claim 1 wherein said sacrificial substrate holder is a concentric ring surrounding said substrate, a second surface of semiconductor substrate being in direct contact with a chuck of said plasma processing chamber.

4. The method of claim 1 wherein said etching is a metallization etch, said material comprising aluminum.

5. The method of claim 4 wherein said etchant source gas includes chlorine.

6. The method of claim 5 wherein said plasma processing chamber represents an inductively coupled plasma processing chamber.

7. The method of claim 1 wherein said semiconductor substrate represents a substrate for fabricating integrated circuits (IC's).

8. The method of claim 1 wherein said plasma processing chamber represents an inductively coupled plasma processing chamber.

9. The method of claim 1 wherein said plasma processing chamber represents a transformer coupled plasma processing chamber.

10. The method of claim 1 wherein said material is selected to form substantially volatile byproducts when etched by said plasma within said plasma processing chamber.

11. A sacrificial substrate holder for improving etch uniformity while etching a semiconductor substrate in a plasma processing chamber, comprising:
a sacrificial etch portion configured to surround said semiconductor substrate, said sacrificial etch portion including a first surface comprising a material capable of being etched by a plasma configured to etch said semiconductor substrate when said semiconductor substrate and said sacrificial substrate holder are disposed on a chuck within said plasma processing chamber,
wherein said first surface of said sacrificial etch portion is substantially parallel to a first surface of said semiconductor substrate when said semiconductor substrate and said sacrificial substrate holder are disposed on said chuck within said plasma processing chamber, thereby permitting said plasma to etch said first surface of said semiconductor substrate and said first surface of said sacrificial etch portion simultaneously.

12. The sacrificial substrate holder of claim 11 wherein said semiconductor substrate represents a wafer and wherein said sacrificial etch portion represents a ring surrounding said wafer.

13. The sacrificial substrate holder of claim 11 wherein said sacrificial substrate holder is a ring surrounding said substrate, a second surface of semiconductor substrate being in direct contact with said chuck of said plasma processing chamber.

14. The sacrificial substrate holder of claim 11 wherein said plasma is configured to etch a metallization layer of said semiconductor substrate, said material comprising aluminum.

15. The sacrificial substrate holder of claim 15 wherein said plasma processing chamber represents an inductively coupled plasma processing chamber.

16. The sacrificial substrate holder of claim 11 wherein said semiconductor substrate represents a substrate for fabricating integrated circuits (IC's).

17. The sacrificial substrate holder of claim 11 wherein said plasma processing chamber represents an inductively coupled plasma processing chamber.

18. The sacrificial substrate holder of claim 11 wherein said plasma processing chamber represents a high density plasma processing chamber.

19. The sacrificial substrate holder of claim 11 wherein said material is selected to form substantially volatile byproducts when etched by said plasma within said plasma processing chamber.

20. In a plasma processing chamber, an apparatus for improving etch uniformity while etching a semiconductor substrate, comprising:
sacrificial means surrounding said semiconductor substrate, said sacrificial means being configured to present a surface means of said sacrificial means to a plasma within said plasma processing chamber to permit said plasma to etch a first surface of said semiconductor substrate and said surface means simultaneously when said semiconductor substrate and said sacrificial means are disposed on a chuck in said plasma processing chamber, said surface means comprising a material capable of being etched by said plasma,
wherein said surface means is substantially parallel to said first surface of said semiconductor substrate when said semiconductor substrate and said sacrificial means are disposed on said chuck within said plasma processing chamber.

21. The apparatus of claim 20 wherein said plasma is configured to etch a metallization layer of said semiconductor substrate, said material comprising aluminum.

22. The apparatus of claim 21 wherein said material comprises substantially pure aluminum.

23. The apparatus of claim 20 wherein said plasma processing chamber represents an inductively coupled plasma processing chamber.

24. The apparatus of claim 20 wherein said material is selected to form substantially volatile byproducts when etched by said plasma within said plasma processing chamber.
